(19) United States
(12) Patent Application Publication
(10) Pub. No.: US 2008/0235541 A1
(43) Pub. Date: Sep. 25, 2008

(54) METHOD FOR TESTING A WORD LINE FAILURE

(75) Inventor: Yuto Ikeda, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 11/688,240

(22) Filed: Mar. 19, 2007

(51) Int. Cl. G11C 29/00

(52) U.S. Cl. 714/721

(57) ABSTRACT

A method for testing a word line failure of a memory device is provided. The memory device comprises a memory cell with a transistor connecting to a word line and a bit line. The method comprises driving the word line to a predetermined voltage level by a word line driver so as to turn off or on the transistor of the memory cell; and reducing the driving ability of the word line drive.

### BACKGROUND OF THE INVENTION

1. Field of the Invention

This invention relates to a memory device. More particular, the present invention relates to a method for testing a word line failure of a memory device before package stage.

2. Description of Related Art

The memory devices have been broadly used in various kinds of electronic devices. The main part of a memory device usually comprises a memory cell array and related circuits for driving and controlling the memory cell array. The memory cell can be a basic 1T1C (one transistor and on capacitor) structure as shown in FIG. 1A. As shown in FIG. 1A, the gate of the transistor T is connected to a word line WL, the drain is connected to a bit line BL, and the source is connected to a capacitor. As the word line is activated for reading, the transistor T is turned on and data stored in the capacitor C is transmitted through the storage node SN, the transistor T, and then to the bit line.

In some situation, like the manufacturing process or others, particles or etching residues created from thereof will cause a short circuit between the word line WL and the bit line BL, i.e., a small resistance will be generated between the word line WL and the bit line BL, as shown in FIG. 1B. The word line WL and the bit line BL are no longer isolated, and this will cause malfunction in reading the memory cell. Following will further discuss the read operation and how the short circuit affects the memory operation.

FIG. 2 shows a schematic structure of a memory cell and its corresponding sense amplifier SA, in which one cell corresponds to two bit lines BL and B̅L̅. The sense amplifier SA can comprise cross-coupled N channel and P channel transistors. A small voltage level difference between the bit lines BL and B̅L̅ can be amplified by the sense amplifier, so that the data stored in the memory cell is read out.

FIG. 3 shows schematic waveforms at an active cycle for reading a normal memory cell. In this case, the word line and the bit line corresponding to the memory cell is not shorted as in FIG. 1A. FIG. 3 explains how to read data of low voltage level. At first, in a standby period, voltage levels of the bit lines BL and B̅L̅ are at ½ Vcc by a BL precharge and equalization circuit. Meanwhile, the word WL is at low voltage level (Vss). When an ACT command is input, the word WL is activated, i.e., selected, and become a high voltage level Vpp. Then, the cell data stored in the capacitor C (low) is read out (transferred) to BL. This makes the bit line BL lower a little, and the bit line B̅L̅ keeps its voltage level (½ Vcc). Next, the sense amplifier SA amplifies the small difference between the bit lines BL and B̅L̅. In this case, the bit line BL becomes a low voltage level (Vss) and the bit line B̅L̅ becomes a high voltage level (Vcc). In the next read period (not shown), the low level data on bit line BL is correctly read out as low (L) to an output pad through I/O lines and data bus lines.

FIG. 4 shows schematic waveforms for reading an abnormal memory cell. In this case, the word line and the bit line are shorted as in FIG. 1B. This will make the low level data incorrectly read out as high level data. FIG. 4 explains that the abnormal word line is selected. Before the word line WL is activated (i.e. in the standby period), the voltage levels of the bit lines BL and B̅L̅ become the same but lower than normal BL level (½ Vcc) as in FIG. 3. During the standby period, the word line WL is at low voltage level, and the word line WL and the bit line BL are shorted. This makes the voltage levels of bit lines BL and B̅L̅ lower. The dropped voltage level of bit lines BL and B̅L̅ depends on the resistance between the word line WL and the bit line BL.

When the word line WL is activated (selected), the low level data of the memory cell is read out to BL. This makes the bit line BL level lower a little. Due to the short circuit between the word line WL and the bit line BL, the voltage level of the bit line BL is pulled up by the word line voltage (Vpp), while the bit line B̅L̅ keeps its voltage level in the standby period. Due to the short circuit, the voltage level of the word line WL is also pulled down, but the voltage drop is only a little because of the strong driving ability of the WL driver. Next, the sense amplifier SA is activated, and then amplifies the voltage difference between bit lines BL and B̅L̅. In this case, the voltage level of the bit line BL approaches to Vcc and the bit line B̅L̅ approaches to Vss. In other words, the data of the memory cell should be read out as low, but is incorrectly read out as high.

The aforementioned is the case of active operation at the memory cell whose WL is shorted to its BL. However, other memory cells on the same BL but connected to a normal WL will also become failure with different mode. Those data always read out as low level because the BL is connected to the shorted WL that is not activated. Therefore, their failure mode is a high-to-low (H->L) error, as shown in FIG. 5.

FIG. 5 shows waveforms of WL and BL of cells on the abnormal BL but connected to normal WL. In this case, it is illustrated that data with high voltage level (H) is stored in the memory cell. When WL is activated (selected), data with high level stored in the cell is read out to the BL. This makes BL voltage level higher a little. However, the BL is sorted to the WL which is not selected. It means the WL is at low voltage level and pulls down the BL voltage level lower, while the B̅L̅ keeps its voltage level in the standby period.

Next, the sense amplifier SA is activated, and a voltage difference between BL and B̅L̅ is amplified. Then, the BL approaches to the voltage level Vss and the B̅L̅ approaches to voltage level Vcc. In normal case, the memory cell should be read as high level, but now the memory cell is incorrectly read out to BL as low level. Therefore, this memory cell is determined as “Fail” (a high-to-low (H->L) failure) in next read cycle (not shown in figure).

FIG. 6 shows the relation of the WL-BL shorted memory cell and other cells. In FIG. 6, the cell with WL-BL short becomes a L->H failure shown as FIG. 4 and other cells on the BL becomes H->L failure as FIG. 5. All cells on the B̅L̅ easily fails in L->H because the voltage level of the abnormal BL is lowered by unselected WL. Therefore, the cells on the B̅L̅ are an L->H failure relatively.

As described above, when the memory cell of DRAM has WL-BL short issue, both lines are connected with some resistance and make noise to each other. Most of the WL-BL short circuit makes only BL failure. Although the word line WL also has noise, it's not so strong because driving ability of the WL driver is strong enough to stably maintain the voltage level of the word line. Thus, no word line failure occurs. As BL failure is determined, the failed BL is repaired by redundant BL so as to recover the BL failure. Then, the DRAM will be subject to a burn-in (BI) test in which voltage and temperature stress are applied thereon to test the reliability of the DRAM. During the BI test, the applied stress and voltage will make the WL-BL short circuit effect stronger. It means the resistance between WL and BL becomes smaller and the noise becomes larger. This noise makes the voltage level of word line WL much lower than normal voltage level to restore high level to memory cell enough. As a result, WL failure of the DRAM is determined just after BI test.

In general, the BI test is performed in a manner that the DRAM has been packaged. Therefore, once the WL failure occurs during the BI test, the WL failure can not be repaired by using the redundant word lines. Therefore, how to find the WL fail before the BI test is an urgent issue. Once the WL failure can be found at the wafer stage, the failed WL can be replaced with the corresponding redundant WL.

### SUMMARY OF THE INVENTION

According to the foregoing description, the present invention provides a method for testing a word line failure of a memory device. The memory device comprises a memory cell with a transistor connecting to a word line and a bit line. The method comprises: driving the word line to a predetermined voltage level by a word line driver so as to turn on the transistor of the memory cell; and reducing the driving ability of the word line driver.

The invention further provides a method for testing a word line failure of a memory device. The memory device comprises a memory cell with a transistor connecting to a word line and a bit line. The method comprises driving the word line to a predetermined voltage level by a word line driver so as to turn off the transistor of the memory cell; and reducing the driving ability of the word line drive.

Base on the invention above, the memory cell array in the wafer stage can be subject to the BL and WL failure test. Therefore, before the BI test is performed, all failed word lines and bit lines can be replaced with the redundant word lines and bit lines. As a result, no more word line failure will occur after the BI test.

### BRIEF DESCRIPTION OF THE DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings.

FIG. 1A shows a normal 1T1C memory cell, and FIG. 1B shows an abnormal 1T1C memory cell that a short circuit occurred between the word line and the bit line.

FIG. 2 shows schematic structure of a memory cell and its corresponding sense amplifier.

FIG. 3 shows schematic waveforms for reading a normal memory cell in a normal mode.

FIG. 4 shows schematic waveforms for reading an abnormal memory cell in a normal mode.

FIG. 5 shows waveforms of WL and BL of cells connected on the abnormal BL (shorted to WL) but connected to normal WL.

FIG. 6 shows the failure modes of the WL-BL shorted memory cell and other cells.

FIG. 7 shows an active cycle waveform of selected abnormal memory cell (WL-BL shorted) in WL failure test mode.

FIG. 8 shows an active cycle waveform of unselected abnormal memory cell (WL-BL shorted) in WL failure test mode.

FIG. 9 shows a waveform of the abnormal WL active and standby cycle in the WL failure test mode.

FIG. 10 shows a WL driving waveform for reducing the driving ability of the WL driver according to the first embodiment of the present invention.

FIG. 11 shows a WL driving waveform for reducing the driving ability of the WL driver according to the second embodiment of the present invention.

FIG. 12 shows a WL driving waveform for reducing the driving ability of the WL driver according to the second embodiment of the present invention.

FIG. 13A shows a conventional WL driver for comparison.

FIG. 13B to 13D shows some examples of the WL driving circuits to achieve the testing method as described above.

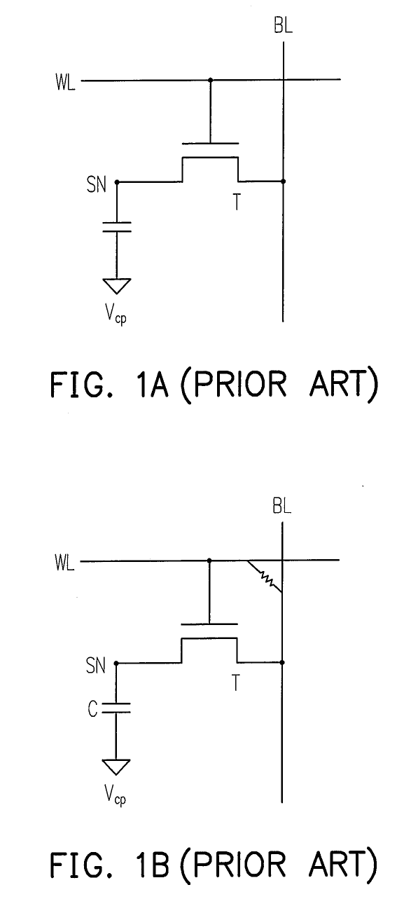

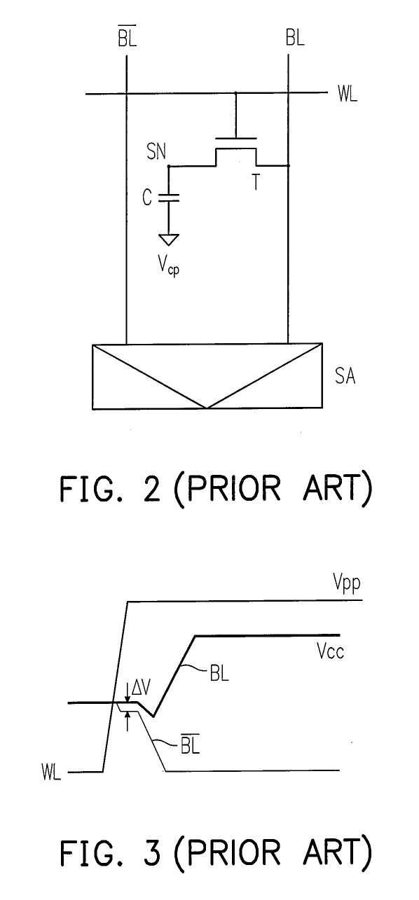

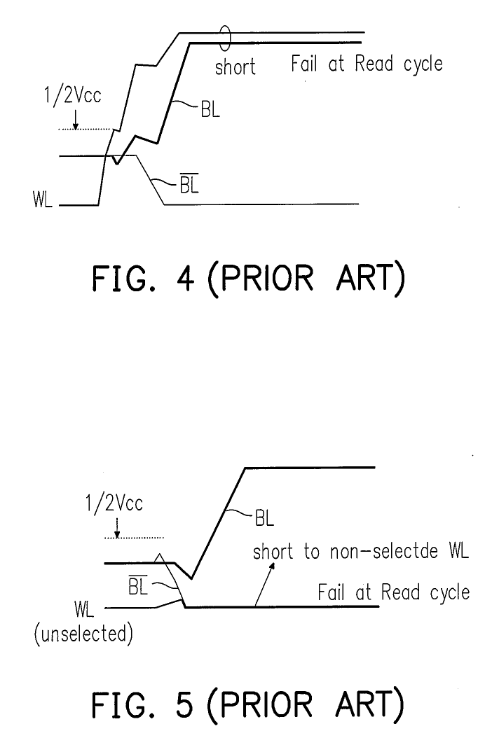

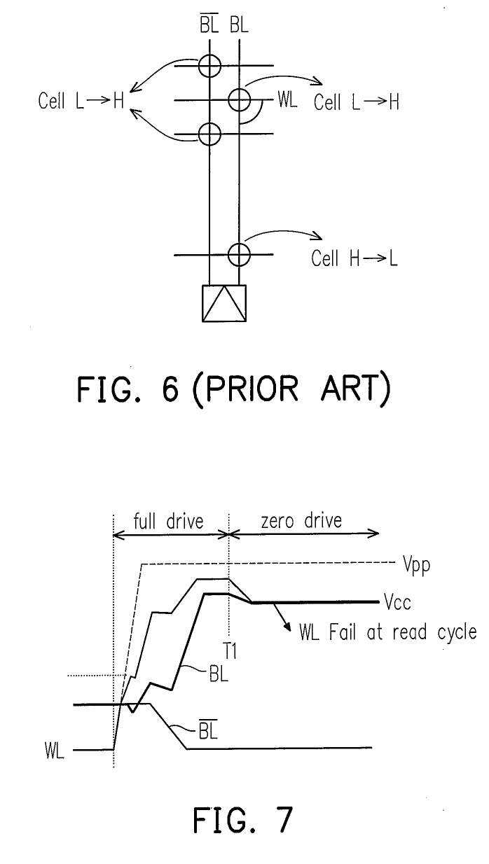

### DESCRIPTION OF THE PREFERRED EMBODIMENT

The embodiments provide a method to reduce the driving ability of the WL driver when the DRAM entry the special test mode (or WL failure test mode). More detail, in this test mode, the WL driver operates only with a period shorter than normal mode (i.e. 1-shot drive). After the period, the driving ability becomes smaller or zero, so that the word line gets noise easily. Then, the WL-BL short can be found as a WL failure. The BL failure is also detected as above. The WL and the BL failures are repaired by redundant WLs and BLs. Therefore, no new failure will be found after the BI test.

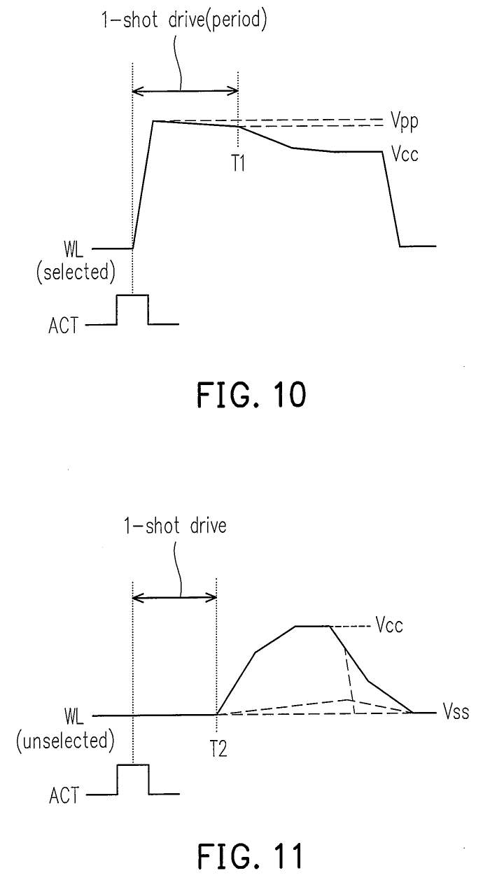

Next, several methods to reduce the driving ability of the WL driver are provided for different condition. FIG. 10 shows a WL driving waveform for reducing the driving ability of the WL driver according to the first embodiment of the present invention, and FIG. 7 shows an active cycle waveform of abnormal memory cell (WL-BL shorted) in WL failure test mode.

As shown in FIG. 10, when the word line shorted to BL is activated in the WL failure test mode, the driving ability of the WL driver is slightly reduced with a small amount or becomes zero at T1 after the beginning of activating the word line. The timing T1 can be controlled by an internal delay circuit, for example a serially connected delay units. This method makes the driving ability of the WL driver lower or zero after 1-shot drive period.

Referring to FIG. 7, before the predetermined timing T1, the WL is driven with its full ability, i.e., with the voltage level Vpp. Then, after the predetermined period T1, the driving ability is reduced from full ability to zero or reduced by a little amount (shown in FIG. 10). FIG. 7 shows the case of zero driving ability, and the WL level is reduced to Vcc due to the disturbance of shorted BL.

When a precharge command is inputted, the WL waveform is pulled down to Vss level, and data of all cells connected to the WL are restored. The voltage level of a normal WL (not shorted to BL) is lower than voltage level Vpp by a little amount; so that the cell with high-level data can be restored as almost full Vcc (Vcc is the bit line voltage level). However, in the WL failure test mode, the voltage level of the abnormal WL (shorted to BL) is almost at the voltage level Vcc. Therefore, the high-level data can be only restored as the voltage level “Vcc-Vth” (Vth: threshold voltage). In next read cycle in normal mode, the data voltage level of the cell is not high enough, which easily results in a high-to-low failure. Then, a WL failure can be determined.

Once the WL failure is determined, the failed word line can be replaced with redundant WL. Since the memory cell array is still not packaged, therefore, the failed WL can be repaired. As a result, when the subsequent BI test is performed, no further WL failure will occur because the failed WL is already repaired.

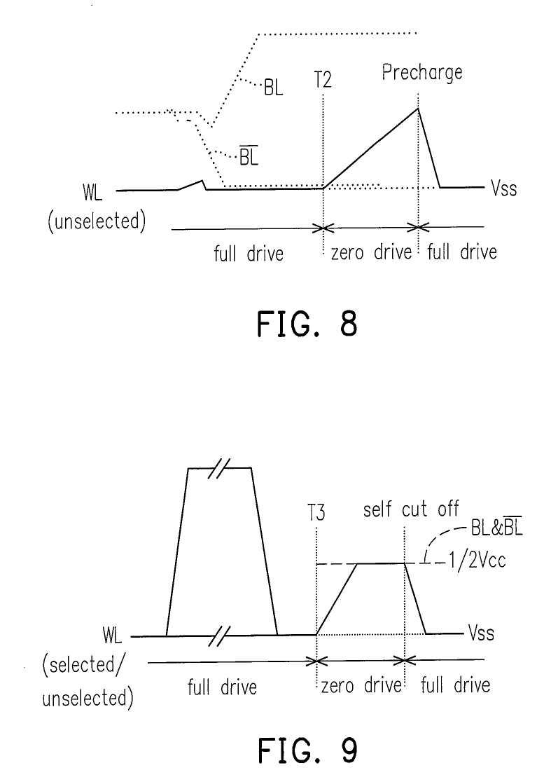

FIG. 11 shows a WL driving waveform for reducing the driving ability of the WL driver according to the second embodiment of the present invention, and FIG. 8 shows an active cycle waveform of unselected abnormal memory cell (WL-BL shorted) in WL failure test mode.

As shown in FIG. 11, in the standby period or active period with the condition of unselecting the word line, the WL voltage level is forced to the voltage level Vss. This method reduces the driving ability to force WL after some delay from ACT command. After reducing the driving ability of the WL driver, the WL voltage level easily become higher than Vss, and turn on all of the memory cells on WL. Then the data stored in those cells are broken, and a WL failure occurs in next normal read cycle.

This method shows a case that the abnormal WL is not selected. As shown in FIG. 11, the fully driving ability of the WL driver for the unselected WL is the lowest voltage level of the WL waveform, i.e., Vss. At the predetermined timing T2, the WL driving ability is reduced from full to zero or reduced by a little amount during the WL failure test mode. As the driving ability is reduced, the WL voltage level is pulled up near to the voltage level Vcc, and then cells on the unselected WL is turned on.

Referring to FIG. 8, when the precharge command is inputted, the driving ability of the WL driver returns to full driving ability. Then, the unselected abnormal WL voltage level is pulled down to Vss, and data of all cells connected to the WL are restored. If the data of the memory cell connected to the selected WL is not the same as the data of the memory cell connected to the unselected WL, the incorrectly restored data makes the WL failure in next read cycle in normal mode. Then, a WL failure can be determined.

Once the WL failure is determined, the failed word line can be replaced with redundant WL. Since the memory cell array is still not packaged, therefore, the failed WL can be repaired. As a result, when the subsequent BI test is performed, no further WL failure will occur because the failed WL is already repaired.

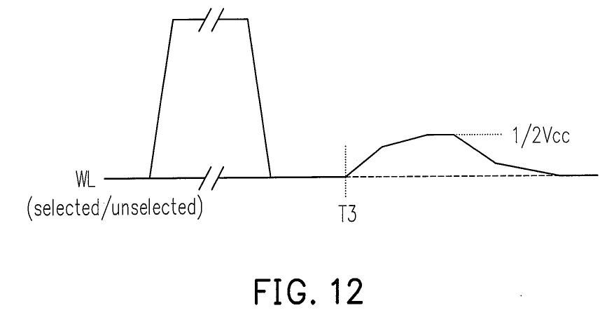

FIG. 12 shows a WL driving waveform for reducing the driving ability of the WL driver according to the third embodiment of the present invention, and FIG. 9 shows a waveform of the abnormal WL active and standby cycle in the WL failure test mode. This embodiment is to reduce the driving ability of the WL driver at a predetermined timing T3 after the precharge command. This procedure also makes the WL voltage level high enough to turn on memory cells in standby period, and therefore to find the WL-BL short as a WL failure.

Referring to FIG. 9, after a predetermined period of precharge command, this WL failure test mode reduces the driving ability of the WL driver from full to zero or reduced by a little amount. Due to being shorted to the bit line, the abnormal WL raises its voltage level from Vss to almost ½ Vcc (BL voltage level). As a result, this WL voltage level turns on all memory cells connected on the abnormal WL, referring to the description of FIG. 8.

The driving ability of the WL driver returns to full after some period since T3, and the WL voltage level is pulled down to Vss normally. The timing of reducing the driving ability can be controlled by an internal delay circuit or any circuit with the same function. When the WL voltage level becomes higher, the raised WL voltage level will destroy the data stored in the cells on the failed WL. As a result, these cells will be incorrectly read out in the next read cycle. For a normal WL, it keeps almost at the voltage level Vss even though the word line is driven by the zero driving ability, because there is no disturbance from BL.

Similarly, once the WL failure is determined, the failed word line can be replaced with redundant WL. Since the memory cell array is still not packaged, therefore, the failed WL can be repaired. As a result, when the subsequent BI test is performed, no further WL failure will occur because the failed WL is already repaired.

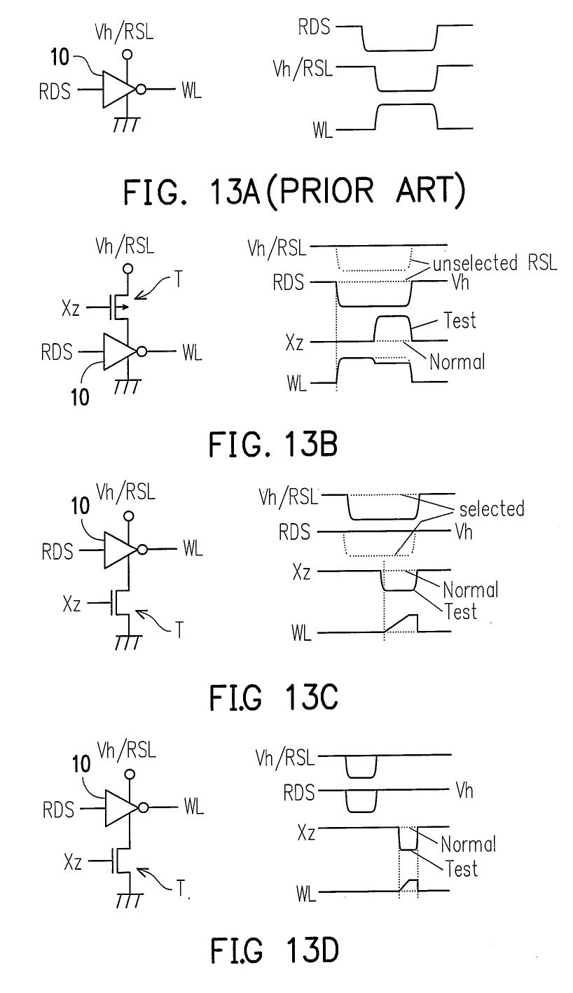

FIG. 13B to 13C shows some examples of the WL driving circuits to achieve the testing method as described above. FIG. 13A shows a conventional WL driver for comparison. In FIGS. 13A-13D, the signals RDS, Vh, RSL and Xz represent a row decoder signal, a high voltage for turning on and driving the WL (larger than Vdd), a row select line signal, and WL Hi-Z signal at the test mode. The circuits and waveform timing of FIGS. 13B, 13C and 13D are respectively to explain FIGS. 7, 8 and 9.

Basically, the circuit for testing a word line failure for a memory array comprises a plurality of word line drivers 10, each of which is coupled the corresponding word line WL; and a control unit T, which is coupled to each of the word line drivers, for reducing a driving ability of a selected word line driver. The control unit is deactivated to reduce the driving ability of the selected word line driver for performing a word line failure test.

In FIGS. 13B/13C, the control unit is a switch circuit that is turned on/off to reduced the driving ability of selected/unselected word line driver. For example, the switch circuit can be constructed by at least a transistor, and a gate of the transistor is used for receiving the control signal. In other design, the control unit is embedded within a timing controller.

In summary, according to the invention, the memory cell array in the wafer stage can be subject to the WL failure test. Therefore, before the BI test in package stage is performed, all failed word lines and bit lines can be replaced with the redundant word lines and bit lines. As a result, no more word line failure will occur after the BI test.

While the present invention has been described with a preferred embodiment this description is not intended to limit our invention. Various modifications of the embodiment will be apparent to those skilled in the art. It is therefore contemplated that the appended claims will cover any such modifications or embodiments as fall within the true scope of the invention.

What is claimed is:

1. A method for testing a word line failure of a memory device, the memory device comprising a memory cell with a transistor connecting to a word line and a bit line, the method comprising:
driving the word line to a predetermined voltage level by a word line driver so as to turn on the transistor of the memory cell; and
reducing the driving ability of the word line driver.

2. As the method of claim 1, wherein the predetermined voltage level of the word line is Vpp.

3. As the method of claim 1, wherein the voltage level of the word line approaches to a voltage level of the bit line after reducing the driving ability of the word line driver.

4. As the method of claim 3, wherein the voltage level of the bit line is Vcc.

5. As the method of claim 3, wherein the word line of the memory cell is shorted to the bit line of the memory cell.

6. As the method of claim 3, wherein a high level data stored in the memory cell is incorrectly read out as a low level data in a next read cycle, and a word line failure is determined.

7. As the method of claim 1, wherein a predetermined timing for reducing the driving ability of the word line driver is controlled by an internal delay circuit.

8. As the method of claim 1, wherein the method is performed before a package stage of the memory device.

9. A method for testing a word line failure of a memory device, the memory device comprising a memory cell with a transistor connecting to a word line and a bit line, the method comprising:
driving the word line to a predetermined voltage level by a word line driver so as to turn off the transistor of the memory cell; and
reducing the driving ability of the word line drive.

10. As the method of claim 9, wherein the predetermined voltage level of the word line is Vss.

11. As the method of claim 9, wherein the voltage level of the word line approaches to a voltage level of the bit line after reducing the driving ability of the word line driver.

12. As the method of claim 11, wherein the word line of the memory cell is shorted to the bit line of the memory cell.

13. As the method of claim 11, wherein the voltage level of the bit line is Vcc or ½ Vcc.

14. As the method of claim 11, wherein the transistor of the memory cell is turned on by the word line after reducing the driving ability of the word line driver, and a data stored in the memory cell is destroyed so that a word line failure is determined in a next read cycle.

15. As the method of claim 9, wherein a predetermined timing for reducing the driving ability of the word line driver is controlled by an internal delay circuit.

16. As the method of claim 9, wherein the method is performed before a package stage of the memory device.
